(19) United States
(12) Patent Application Publication
(10) Pub. No.: US 2016/0282687 A1
(43) Pub. Date: Sep. 29, 2016

(54) DISPLAY PANEL

(71) Applicant: InnoLux Corporation, Jhu-Nan (TW)

(72) Inventors: Chien-Hung CHEN, Jhu-Nan (TW); Shu-Chan HSIAO, Jhu-Nan (TW)

(21) Appl. No.: 15/077,457

(22) Filed: Mar. 22, 2016

(30) Foreign Application Priority Data
Mar. 23, 2015 (TW) 104109247

(51) Int. Cl. G02F 1/1362; G06F 3/044; G02F 1/1335; G02F 1/1333; H01L 27/12; G02F 1/1368

(52) U.S. Cl. CPC G02F 1/136213; H01L 27/124; H01L 27/1255; H01L 27/1248; G02F 1/1368; G02F 1/136227; G02F 1/133514; G02F 1/13338; G06F 3/044

(57) ABSTRACT

An active-matrix substrate of display panel includes a transparent substrate and capacitor structures including first and second metal layers, first and second and third insulating layers, a conductive layer, a transparent conductive layer disposed above the transparent substrate. The second metal layer disposed on the first insulating layer partially overlaps a region of the first metal layer. The second insulating layer is disposed on the second metal layer. The conductive layer disposed on the second insulating layer partially overlaps a region of the second metal layer. The third insulating layer is disposed on the conductive layer. The transparent conductive layer is insulated from the conductive layer, and is electrically connected with the second metal layer. The transparent conductive layer partially overlaps a region of the conductive layer.

### CROSS REFERENCE TO RELATED APPLICATIONS

This Non-provisional application claims priority under 35 U.S.C. §119(a) on Patent Application No(s). 104109247 filed in Taiwan, Republic of China on Mar. 23, 2015, the entire contents of which are hereby incorporated by reference.

### BACKGROUND

1. Technical Field

This disclosure relates to a display panel.

2. Related Art

Liquid crystal display (LCD) apparatuses have advantages such as low power consumption, less heat generation, less weight and less radiation, so they have been applied to various electronic products and gradually replace the traditional cathode ray tube display (CRT) display apparatuses.

Generally, the LCD apparatus includes an LCD panel and a backlight module. The LCD panel includes a thin film transistor (TFT) substrate, a color filter substrate and a liquid crystal layer disposed between the two substrates. The two substrates and the liquid crystal layer form a plurality of pixels disposed in an array. The backlight module distributes the light from a light source to the LCD panel, and therefore the pixels can display colors to form images.

In one pixel structure, the voltage drops across the liquid crystal (LC) capacitor and the storage capacitor control the liquid crystals to twist or rotate or tilt. However, since the storage capacitor is formed by two opaque electrode layers disposed oppositely, the storage capacitor causes the reduction of the aperture ratio of the pixel. Furthermore, in a display panel with high resolution, the area of one pixel structure is configured to be smaller which causes the LC capacitor also becomes smaller. To avoid raising the kick-back voltage resulted from the gate-drain capacitance (Cgd) when the transistor in the pixel structure is turned off, the capacitance of the storage capacitor needs being larger, and therefore, the aperture ratio of the pixel becomes lower.

Therefore, a display panel with a kept or even raised aperture ratio as well as a larger storage capacitor so as to enhance display performance is needed.

### SUMMARY

This disclosure is to provide a display panel with a kept or even raised aperture ratio as well as a larger storage capacitor so as to enhance display performance.

A display panel of an embodiment according to this disclosure includes an active-matrix substrate. The active-matrix substrate includes a transparent substrate and a plurality of capacitor structures disposed on the transparent substrate. At least one of the capacitor structures includes a first metal layer, a first insulating layer, a second metal layer, a second insulating layer, a conductive layer, a third insulating layer and a transparent conductive layer. The first metal layer is disposed on the transparent substrate. The first insulating layer is disposed on the first metal layer. The second metal layer is disposed on the first insulating layer, and the second metal layer partially overlaps a region of the first metal layer orthogonally projected on the transparent substrate. The second insulating layer is disposed on the second metal layer. The conductive layer is disposed on the second insulating layer, and the conductive layer partially overlaps a region of the second metal layer orthogonally projected on the transparent substrate. The third insulating layer is disposed on the conductive layer. The transparent conductive layer is spatially insulated from the conductive layer, and is electrically connected with the second metal layer. A region of the transparent conductive layer orthogonally projected on the transparent conductive layer and a region of the conductive layer orthogonally projected on the transparent substrate partially overlap.

In one embodiment, the conductive layer and the first metal layer are coupled to a common voltage.

In one embodiment, the display panel further comprises a via hole passing through the second insulating layer and the third insulating layer. The transparent conductive layer is electrically connected with the second metal layer through the via hole.

In one embodiment, a first opening of the conductive layer is larger than a second opening of the second insulating layer.

In one embodiment, the material of the first metal layer, the second metal layer or the conductive layer is selected from at least one of metal, alloy, metal oxide, graphene and silicene, and the first metal layer, the second metal layer or the conductive layer is a single-layer structure or a multi-layer structure.

In one embodiment, the display panel further comprises a planarization layer disposed between the transparent conductive layer and the third insulating layer or between the conductive layer and the second insulating layer.

In one embodiment, the overlap of the first metal layer and the second metal layer forms a first capacitor, the overlap of the conductive layer and the transparent conductive layer forms a second capacitor, and the ratio of the capacitance of the second capacitor to the capacitance of the first capacitor is greater than 1 and less than 5.

In one embodiment, the overlap of the second metal layer and the conductive layer forms a third capacitor, and the sum of the capacitances of the first capacitor, the second capacitor and the third capacitor is regarded as the capacitance of the capacitor structure.

In one embodiment, the display panel further comprises a color filter substrate disposed opposite the active-matrix substrate. A liquid crystal layer is disposed between the color filter substrate and the active-matrix substrate. The active-matrix substrate comprises a plurality of pixel units, at least one of the pixel units corresponds to an LC capacitance for the liquid crystal layer and the capacitance of the capacitor structure, and the ratio of the capacitance of the capacitor structure to the LC capacitance is greater than 1.5 in each of the pixel units.

In one embodiment, the active-matrix substrate comprises a plurality of pixel units, each of the pixel units has an aperture area, and the ratio of the area of the conductive layer to the area of the aperture area is less than 0.8.

In one embodiment, the transparent conductive layer at least partially overlaps the second metal layer.

In one embodiment, the thickness of the planarization layer is greater than the triple of the thickness of the first insulating layer.

In one embodiment, the display panel further comprising a color filter substrate disposed opposite the active-matrix substrate. A liquid crystal layer is disposed between the color filter substrate and the active-matrix substrate. A capacitive touch structure is disposed on at least one side of the color filter substrate.

In one embodiment, the capacitive touch structure is disposed between a filter layer and the color filter substrate.

In one embodiment, the conductive layer is between the transparent conductive layer and the second metal layer.

In one embodiment, the active-matrix substrate further comprises a plurality of pixel units disposed on the transparent substrate to form an array. Each of the pixel units includes a first area and a second area. The first area and the second area comprise the corresponding capacitor structures, and individually correspond to a first transparent conductive layer and a second transparent conductive layer. The first transparent conductive layer and the second transparent conductive layer are provided with different voltages.

As mentioned above, in addition to the first metal layer, the second metal layer and the transparent conductive layer, the capacitor structure of the display panel of this disclosure is further configured with an additional conductive layer, so the capacitance of the storage capacitor can be increased by the overlapping the additional conductive layer and the transparent conductive layer in a direction vertical to the transparent substrate. Because the capacitance of the storage capacitor becomes increased due to the conductive layer, the capacitor formed by the first metal layer and the second metal layer can be designed with smaller capacitance, namely the area of the second metal layer can be decreased appropriately. Thus, the aperture ratio of the pixel can be increased. Accordingly, the aperture ratio of the display panel can be kept or even increased while the capacitance of the storage capacitor is increased, so the display performance can be enhanced. The material of the first metal layer, the second metal layer or the conductive layer in the above embodiments can be selected from at least one of metal, alloy, metal oxide, graphene and silicene, and the first metal layer, the second metal layer or the conductive layer may be a single-layer structure or a multi-layer structure.

### BRIEF DESCRIPTION OF THE DRAWINGS

The embodiments will become more fully understood from the detailed description and accompanying drawings, which are given for illustration only, and thus are not limitative of the present invention, and wherein:

FIG. 1A is a schematic diagram of a pixel unit of a display panel of the first embodiment of this disclosure;

FIG. 1B is a schematic sectional diagram of a capacitor structure of the display panel of the first embodiment of this disclosure along the line A-A′ in FIG. 1A;

FIG. 2 is a schematic diagram of the capacitor structure of the second embodiment of this disclosure;

FIG. 3 is a schematic diagram of the capacitor structure of the third embodiment of this disclosure; and

FIG. 4A, FIG. 4B and FIG. 4C are schematic diagrams of a pixel unit of a display panel of the fourth embodiment of this disclosure.

### DETAILED DESCRIPTION OF THE INVENTION

The embodiments of the invention will be apparent from the following detailed description, which proceeds with reference to the accompanying drawings, wherein the same references relate to the same elements.

For example, the display panel of this disclosure may be a liquid crystal display (LCD) panel, and the LCD panel may be a VA (vertical alignment) display panel or a TN (twisted nematic) display panel.

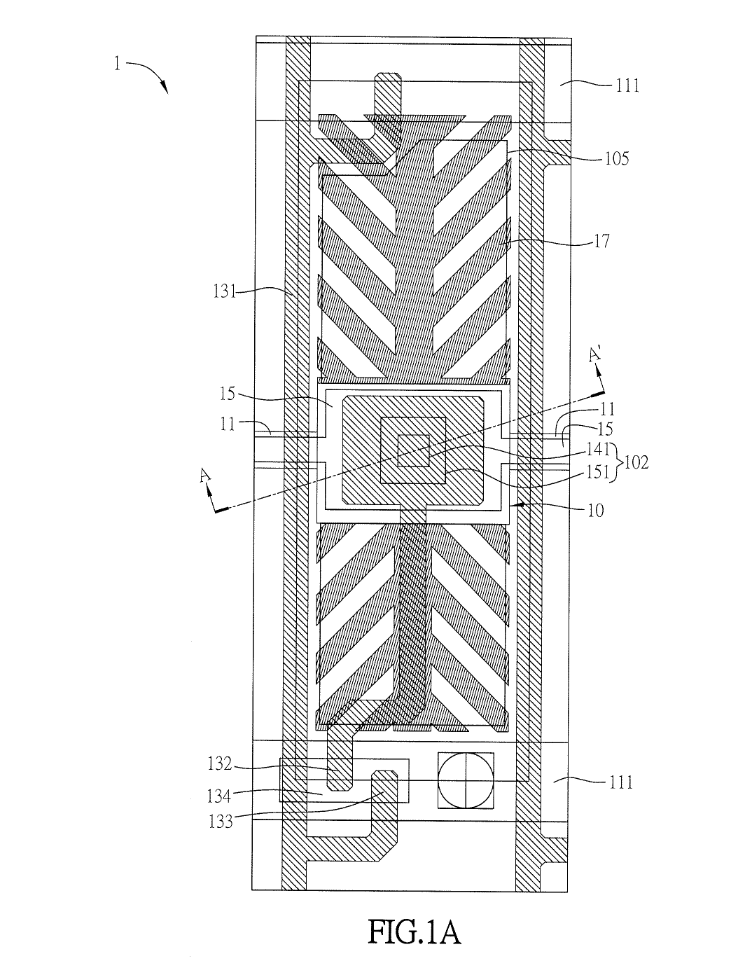

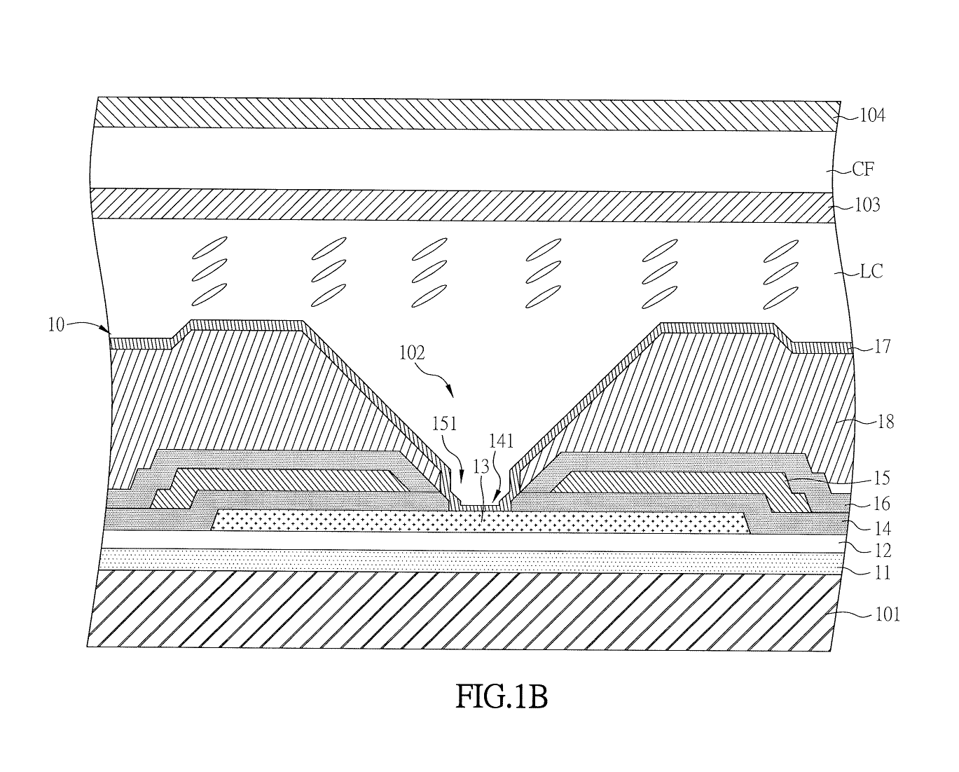

FIG. 1A is a schematic diagram of a pixel unit of a display panel of the first embodiment of this disclosure, and FIG. 1B is a schematic sectional diagram along the line A-A′ in FIG. 1A to show the capacitor structure of the first embodiment of this disclosure. As shown in FIGS. 1A and 1B, the pixel unit 1 includes a first metal layer 11, a first insulating layer 12, a second metal layer 13, a second insulating layer 14, a conductive layer 15, a third insulating layer 16 and a transparent conductive layer 17. An LCD panel is taken as an example in this embodiment, and the LCD panel includes an active-matrix substrate. The active-matrix substrate includes a transparent substrate 101 and a plurality of pixel units disposed on the transparent substrate 101 to form an array. Each of the pixel units 1 includes an active element such as a thin film transistor (TFT), at least a capacitor structure 10, a data line 131 which is formed by patterning the second metal layer 13 and a scan line 111 which is formed by patterning the first metal layer 11. In this embodiment, the pixel unit 1 covers the range of one pixel (e.g. a sub-pixel) of the LCD panel for the illustrative purpose. As shown in FIG. 1A, a TFT includes a drain 132, a source 133 and a semiconductor layer 134. The semiconductor layer 134 may be made of amorphous silicon (a-Si), poly-Si, microcrystal or IGZO (indium gallium zinc oxide), and the line width of the scan line 111 may be designed as greater than the width of the semiconductor layer 134 by 1 μm or more for example.

A capacitor structure 10 includes a first metal layer 11, a first insulating layer 12, a second metal layer 13, a second insulating layer 14, a conductive layer 15, a third insulating layer 16 and a transparent conductive layer 17. The transparent substrate 101 may be a glass substrate, a plastic substrate or a polymer thin film substrate (e.g. polyimide). The above-mentioned metal layers, insulating layers, conductive layer and transparent conductive layer can be patterned by the photolithography process. The related illustration is given as below by a capacitor structure 10.

The first metal layer 11 is disposed on a transparent substrate 101 and patterned to form the bottom electrode of the first capacitor C1. The material of the first metal layer 11 may be selected from at least one of metal, alloy, metal oxide, graphene and silicene, for example, aluminum, copper, silver, molybdenum, wolfram, tantalum, titanium or any alloy thereof The first metal layer 11 may be a single-layer or multi-layer structure made of the above materials. The multi-layer structure may be formed by the stacking layers with the same material or different materials. In the active-matrix substrate (e.g. the TFT substrate), the first metal layer 11 also can be patterned to form the scan line and the gate of the TFT.

The patterned first insulating layer 12 is disposed on the first metal layer 11. The material of the first insulating layer 12 may include SiOx, SiNx or other insulating materials. In the active-matrix substrate, the first insulating layer 12 also can act as the gate insulating layer.

The second metal layer 13 is disposed and patterned on the first insulating layer 12. The second metal layer 13 at least partially overlaps a region of the first metal layer 11 projected orthogonally on the transparent substrate 101, that is, an orthogonally projection of the second metal layer 13 on the transparent substrate 101 partially overlaps an orthogonally projection of the first metal layer 11 on the transparent substrate 101. The overlap of the first metal layer 11 and the second metal layer 13 form a first capacitor C1 in which the first metal layer 11 is the bottom electrode of the first capacitor C1 and the second metal layer 13 is the top electrode of the first capacitor C1. The second metal layer 13 is electrically insulated from the first metal layer 11 by the spatial insulation. The spatial insulation refers to that, for example, the second metal layer 13 is electrically insulated from the first metal layer 11 by the first insulating layer 12. The material of the second metal layer 13 may be selected from at least one of metal, alloy, metal oxide, graphene and silicene, for example, aluminum, copper, silver, molybdenum, wolfram, tantalum, titanium or any alloy thereof. The second metal layer 13 may be a single-layer or multi-layer structure made of the above materials. The multi-layer structure may be formed by stacking layers one by one with the same material or different materials. The second metal layer 13 and the first metal layer 11 may be made of the same material to reduce the production cost. In the active-matrix substrate, the second metal layer 13 also can be patterned to form the data line 131 and the drain 132 and source 133 of the TFT.

The second insulating layer 14 is disposed on the second metal layer 13. The material of the second insulating layer 14 may include SiOx, SiNx or other insulating materials.

The conductive layer 15 is disposed and patterned on the second insulating layer 14, and the conductive layer 15 at least partially overlaps a region of the second metal layer 13 orthogonally projected on the transparent substrate 101, that is, an orthogonally projection of the conductive layer 15 on the transparent substrate 101 partially overlaps an orthogonally projection of the second metal layer 13 on the transparent substrate 101. The overlap of the second metal layer 13 and the conductive layer 15 form a third capacitor C3, and the second metal layer 13 is the bottom electrode of the third capacitor C3 and the conductive layer 15 is the top electrode of the third capacitor C3. The conductive layer 15 is electrically insulated from the second metal layer 13 by the spatial insulation. The spatial insulation refers to that, for example, the conductive layer 15 is electrically insulated from the second metal layer 13 by the second insulating layer 14. The material of the conductive layer 15 may be selected from at least one of metal, alloy, metal oxide, graphene and silicene, for example, aluminum, copper, silver, molybdenum, wolfram, tantalum, titanium or any alloy thereof. The metal oxide is, for example, transparent conducting oxide (TCO). The conductive layer 15 may be a single-layer or multi-layer structure made of the above materials. The multi-layer structure may be formed by stacking layers with the same material or different materials. In this embodiment, the first metal layer 11 and the conductive layer 15 are coupled to a common voltage.

The third insulating layer 16 is disposed and patterned on the conductive layer 15. The material of the third insulating layer 16 may include SiOx, SiNx or other insulating materials.

In addition, the pixel unit 1 of this embodiment may further include a planarization layer 18, which is disposed between the transparent conductive layer 17 and the third insulating layer 16. The material of the planarization layer 18 includes low dielectric photoresist material for example. Besides, the thickness of the planarization layer 18 may be greater than the triple of the thickness of the first insulating layer 12.

The patterned transparent conductive layer 17 is spatially insulated from the conductive layer 15. The regions of the transparent conductive layer 17 orthogonally projected on the transparent substrate 101 at least partially overlaps the conductive layer 15. Furthermore, the region of the transparent conductive layer 17 orthogonally projected on the transparent substrate 101 at least partially overlaps the second metal layer 13. The overlap of the transparent conductive layer 17 and the conductive layer 15 forms a second capacitor C2, and the conductive layer 15 is the bottom electrode of the second capacitor C2 and the transparent conductive layer 17 is the top electrode of the second capacitor C2. The transparent conductive layer 17 is electrically insulated from the conductive layer 15 by the spatial insulation. The spatial insulation refers to that, for example, the transparent conductive layer 17 is electrically insulated from the conductive layer 15 by the third insulating layer 16. In this embodiment, the transparent conductive layer 17 is further electrically insulted from the conductive layer 15 by the planarization layer 18. In the active-matrix substrate, the transparent conductive layer 17 acts as the pixel electrode and is electrically connected with the drain 132 of the TFT for example. The material of the transparent conductive layer 17 includes transparent conducting oxide which is, for example but not limited to, indium-tin oxide (ITO) or indium-zinc oxide (IZO). The display panel further includes a via hole 102. The via hole 102 passes through the second insulating layer 14 and the third insulating layer 16, and the transparent conductive layer 17 is electrically connected with the second metal layer 13 through the via hole 102. Herein, the via hole 102 further passes through the planarization layer 18. As shown in FIG. 1B, a first opening 151 of the conductive layer 15 is larger than a second opening 141 of the second insulating layer 14, so the transparent conductive layer 17 is electrically insulated from the conductive layer 15 spatially.

In this embodiment, the sum of the capacitances of the first capacitor C1, the second capacitor C2 and the third capacitor C3 is regarded as the capacitance of the capacitor structure 10. As shown in FIG. 1B, the display panel may further include a color filter substrate CF. The color filter substrate CF is disposed opposite the active-matrix substrate, and a liquid crystal layer LC is disposed between the color filter substrate CF and the active-matrix substrate. Besides, a filter layer 103 is disposed on the color filter substrate CF, and a capacitive touch structure 104 is disposed on at least one side of the color filter substrate CF to provide the touch function. Herein, the capacitive touch structure 104 is disposed, for example, on a side of the color filter substrate CF farther from the liquid crystal layer LC. The active-matrix substrate includes a plurality of pixel units 1. Each of the pixel units 1 corresponds to an LC capacitance for the liquid crystal layer, and the ratio of the capacitance (Cst) of the capacitor structure 10 to the LC capacitance (Clc) is greater than 1.5 in each pixel unit 1. The capacitive touch structure 104 shown in FIG. 1B is disposed on the upper surface of the color filter substrate CF as an example, but it also may be disposed between the filter layer 103 and the color filter substrate CF in another embodiment. Otherwise, the capacitive touch structure 104 (not shown) may be disposed on each of the upper and lower sides of the color filter substrate CF. For example, the material of the capacitive touch structure 104 may be ITO, IZO, graphene, silicene, metal nanowire, metal (patterned into metal grid wires with the aperture ratio of the light penetration greater than 90% and the metal wire width between 0.08 μm and 8 μm), etc.

In this embodiment, because the liquid crystal is driven by the voltage drop across the LC capacitor formed by the common electrode and the pixel electrode, the driving of the liquid crystal may be less effective if the conductive layer located under the pixel electrode and coupled with the common voltage occupies a much greater area. Therefore, as shown in FIG. 1A, the ratio of the area of the conductive layer 15 to the area of an aperture area 105 of the pixel unit 1 is less than 0.8 in this embodiment. Besides, the conductive layer 15 is covered by the transparent conductive layer 17 in the direction which is vertical to the transparent substrate 101. As a result, the above-mentioned effect can be achieved too, but it is not necessary to concurrently satisfy the above two conditions.

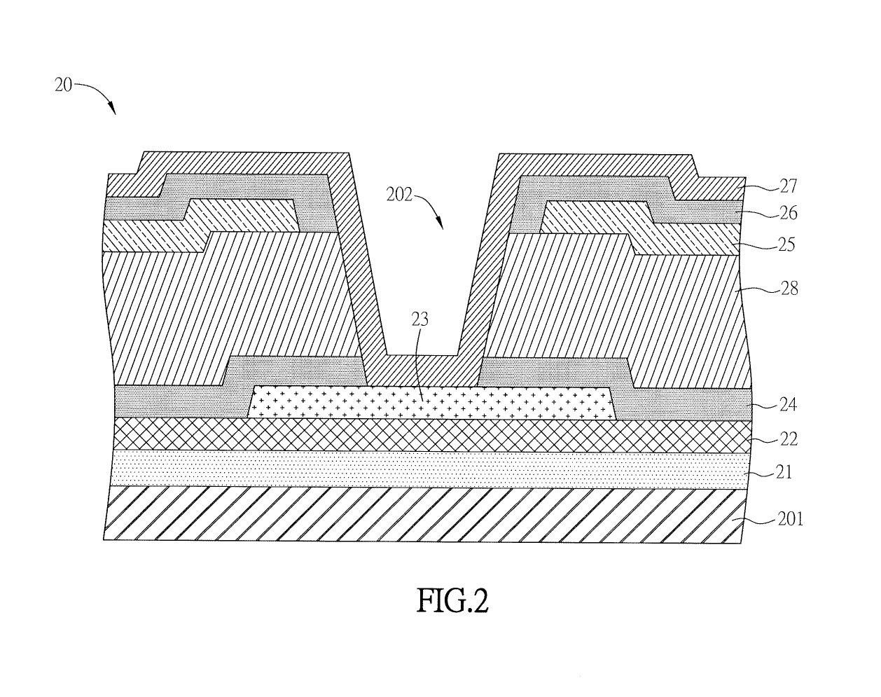

FIG. 2 is a schematic diagram of the capacitor structure 20 of the second embodiment of this disclosure. As shown in FIG. 2, the capacitor structure 20 is disposed on a transparent substrate 201 and includes a first metal layer 21, a first insulating layer 22, a second metal layer 23, a second insulating layer 24, a conductive layer 25, a third insulating layer 26, a transparent conductive layer 27 and a planarization layer 28. Because the capacitor structure 20 is similar to the capacitor structure 10 of the first embodiment, the following illustration mainly describes their difference.

As shown in FIG. 2, a difference from the capacitor structure 10 of the first embodiment is that the planarization layer 28 of the capacitor structure 20 is disposed on the second insulating layer 24 and it is between the second insulating layer 24 and the conductive layer 25. The material of the conductive layer 25 is transparent conducting oxide, for example ITO, IZO, graphene, silicene or other transparent conducting materials. In this embodiment, the overlap of the first metal layer 21 and the second metal layer 23 forms a first capacitor C1, the overlap of the conductive layer 25 and the transparent conductive layer 27 forms a second capacitor C2, and the ratio of the capacitance of the second capacitor C2 to the capacitance of the first capacitor C1 is greater than 1 and less than 5. Like the first embodiment, the ratio of the area of the conductive layer 25 to the area of an aperture area 105 of the pixel unit 1 is less than 0.8. The overlap of the second metal layer 23 and the conductive layer 25 forms a third capacitor C3, wherein the second metal layer 23 is the bottom electrode of the third capacitor C3 and the conductive layer 25 is the top electrode of the third capacitor C3. The sum of the capacitances of the first capacitor C1, the second capacitor C2 and the third capacitor C3 is regarded as the capacitance of a capacitor structure 20.

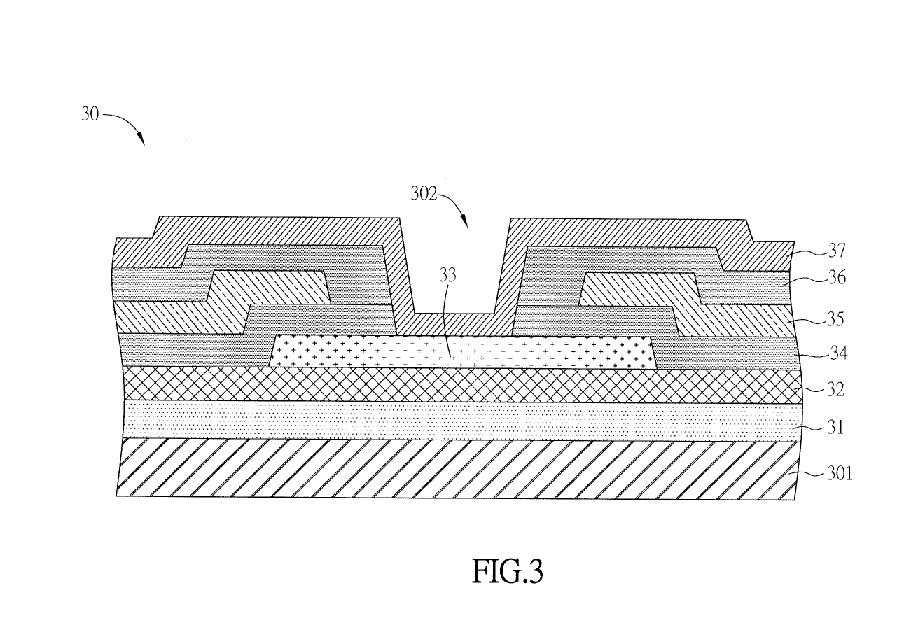

FIG. 3 is a schematic diagram of the capacitor structure 30 of the third embodiment of this disclosure. As shown in FIG. 3, the capacitor structure 30 is disposed on a transparent substrate 301 and includes a first metal layer 31, a first insulating layer 32, a second metal layer 33, a second insulating layer 34, a conductive layer 35, a third insulating layer 36 and a transparent conductive layer 37. Because the capacitor structure 30 is similar to the capacitor structure 10 of the first embodiment, the following illustration mainly describes their difference.

As shown in FIG. 3, a difference from the capacitor structure 10 of the first embodiment is that there is no planarization layer in the capacitor structure 30. The material of the conductive layer 35 is transparent conducting oxide, for example ITO, IZO, graphene, silicene or other transparent conducting materials. In this embodiment, the overlap of the first metal layer 31 and the second metal layer 33 forms a first capacitor C1, the overlap of the conductive layer 35 and the transparent conductive layer 37 forms a second capacitor C2, and the ratio of the capacitance of the second capacitor C2 to the capacitance of the first capacitor C1 is greater than 1 and less than 5. Moreover, the transparent conductive layer 37 of this embodiment is electrically connected with the second metal layer 33 through a via hole 302. Herein, the via hole 302 passes through the third insulating layer 36 and the second insulating layer 34. The overlap of the second metal layer 33 and the conductive layer 35 forms a third capacitor C3, the second metal layer 33 is the bottom electrode of the third capacitor C3 and the conductive layer 35 is the top electrode of the third capacitor C3. The sum of the capacitances of the first capacitor C1, the second capacitor C2 and the third capacitor C3 is regarded as the capacitance of a capacitor structure 30.

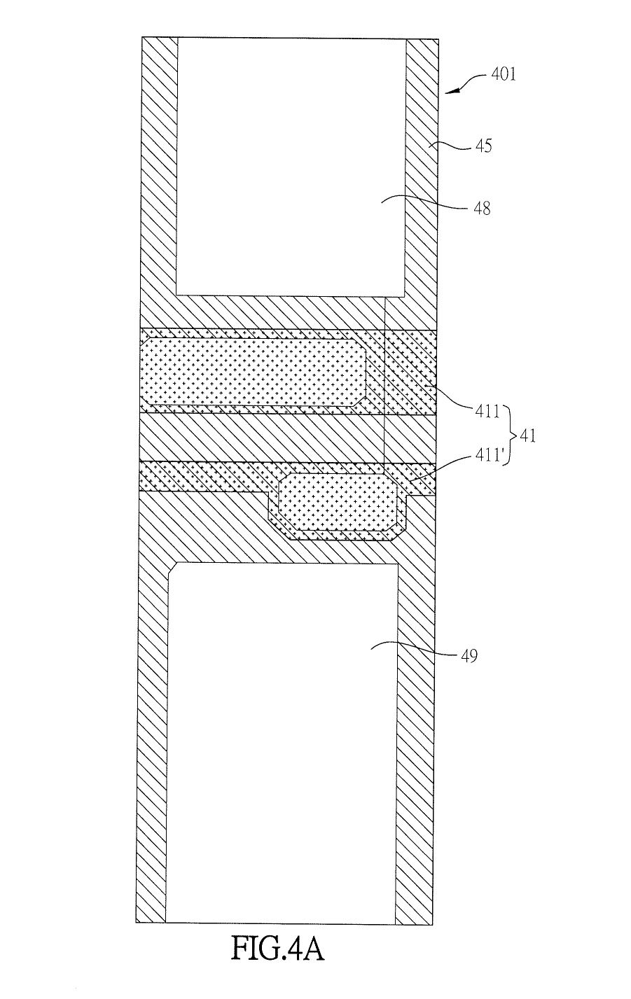

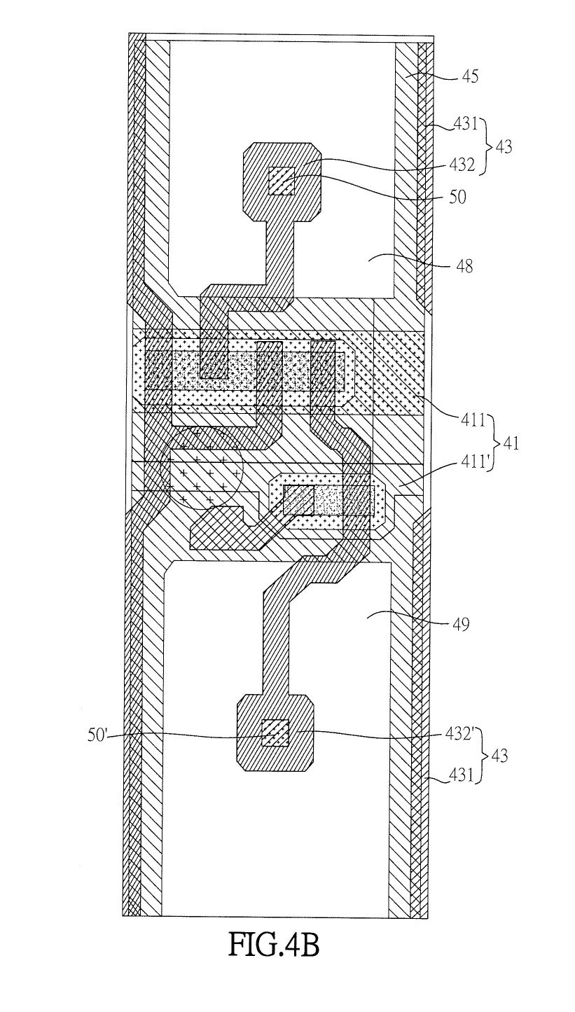

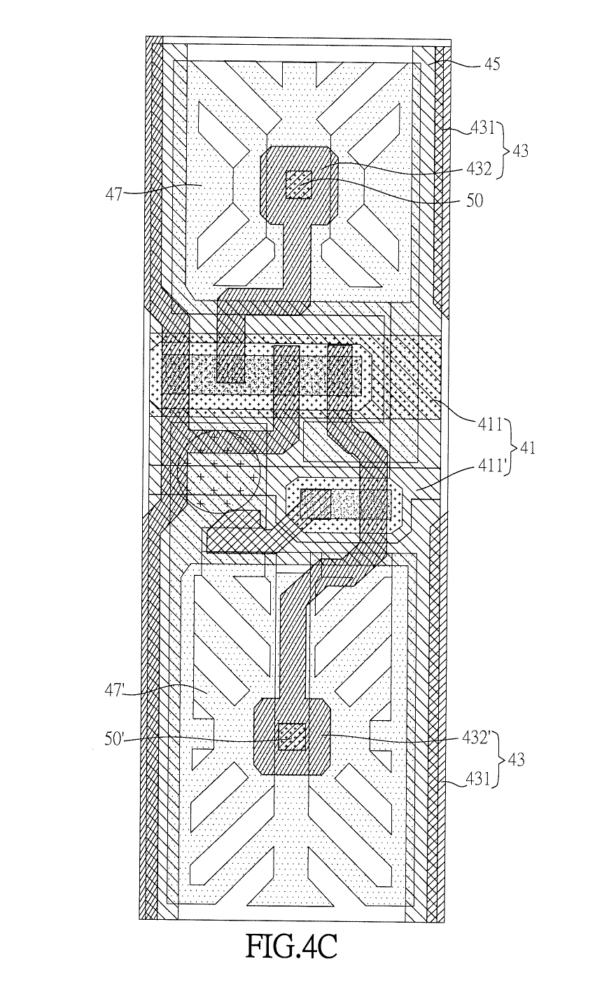

FIG. 4A, FIG. 4B and FIG. 4C are schematic diagrams of a pixel unit of a display panel of the fourth embodiment of this disclosure. In this embodiment, the LCD panel is a VA (vertical alignment) display panel for example, and the pixel unit includes a first area and a second area. It can improve side-view quality by providing different voltages respectively for these areas. FIG. 4A illustrates a transparent substrate 401, a first metal layer 41, a conductive layer 45, a first area 48 and a second area 49. The first metal layer 41 is disposed on the transparent substrate 401. The difference between FIG. 4B and FIG. 4A is that FIG. 4B additionally illustrates a second metal layer 43, a first via hole 50 and a second via hole 50′. The patterned second metal layer 43 forms a data line 431, a drain 432 and a drain 432′. The patterned first metal layer 41 forms a first scan line 411 and a second scan line 411′. FIG. 4C additionally illustrates a first transparent conductive layer 47 and a second transparent conductive layer 47′. By providing driving signals respectively for the first scan line 411 and the second scan line 411′ at different times, the data on the data line 431 are sent to the first transparent conductive layer 47 through the first drain 432 and the first via hole 50 and sent to the second transparent conductive layer 47′ through the second drain 432′ and the second via hole 50′. Thus, it can improve side-view quality.

Similar to the previous first to third embodiments, in the fourth embodiment, the first area and the second area comprise corresponding capacitor structures. The capacitor structure comprises a first insulating layer (not shown), a second insulating layer (not shown), and a third insulating layer (not shown). The first insulating layer is disposed between the first metal layer 41 and the second metal layer 43. The second metal layer 43 at least partially overlaps a region of the first metal layer 41 orthogonally projected on the transparent substrate 401. The second insulating layer is disposed between the second metal layer 43 and the conductive layer 45. The conductive layer 45 at least partially overlaps a region of the second metal layer 43 orthogonally projected on the transparent substrate 401. The third insulating layer is disposed between the conductive layer 45 and the first transparent conductive layer 47 (or the transparent conductive layer 47′). The conductive layer 45 and the first transparent conductive layer 47 (or the transparent conductive layer 47′) are electrically insulated from each other, and the first transparent conductive layer 47 (or the transparent conductive layer 47′) at least partially overlaps the conductive layer 45 orthogonally projected on the transparent substrate 401. The conductive layer 45 is coupled to a common voltage level. In this embodiment, the conductive layer 45 is between the first transparent conductive layer 47 (or the transparent conductive layer 47′) and the second metal layer 43. Compared with the conventional device, the device in the embodiment can have better aperture ratio.

Summarily, in addition to the first metal layer, the second metal layer and the transparent conductive layer, the capacitor structure of the display panel of this disclosure is further configured with an additional conductive layer, so the capacitance of the storage capacitor can be increased by the overlapping the additional conductive layer and the transparent conductive layer in a direction vertical to the transparent substrate. Because the capacitance of the storage capacitor becomes increased due to the conductive layer, the capacitor formed by the first metal layer and the second metal layer can be designed with smaller capacitance, namely the area of the second metal layer can be decreased appropriately. Thus, the aperture ratio of the pixel can be increased. Accordingly, the aperture ratio of the display panel can be kept or even increased while the capacitance of the storage capacitor is increased, so the display performance can be enhanced. The material of the first metal layer, the second metal layer or the conductive layer in the above embodiments can be selected from at least one of metal, alloy, metal oxide, graphene and silicene, and the first metal layer, the second metal layer or the conductive layer may be a single-layer structure or a multi-layer structure.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display panel, comprising:
an active-matrix substrate comprising a transparent substrate and a plurality of capacitor structures disposed on the transparent substrate, at least one of the capacitor structures comprising:
a first metal layer disposed on the transparent substrate;
a first insulating layer disposed on the first metal layer;
a second metal layer disposed on the first insulating layer, wherein the second metal layer partially overlaps a region of the first metal layer;
a second insulating layer disposed on the second metal layer;
a conductive layer disposed on the second insulating layer, wherein the conductive layer partially overlaps a region of the second metal layer;
a third insulating layer disposed on the conductive layer; and
a transparent conductive layer insulated from the conductive layer and electrically connected with the second metal layer, wherein the transparent conductive layer partially overlaps a region of the conductive layer.

2. The display panel as recited in claim 1, wherein the conductive layer and the first metal layer are coupled to a common voltage.

3. The display panel as recited in claim 2, further comprising:
a via hole passing through the second insulating layer and the third insulating layer, wherein the transparent conductive layer is electrically connected with the second metal layer through the via hole.

4. The display panel as recited in claim 3, wherein a first opening of the conductive layer is larger than a second opening of the second insulating layer.

5. The display panel as recited in claim 1, wherein the material of the first metal layer, the second metal layer or the conductive layer is selected from at least one of metal, alloy, metal oxide, graphene and silicene, and the first metal layer, the second metal layer or the conductive layer is a single-layer structure or a multi-layer structure.

6. The display panel as recited in claim 1, further comprising:
a planarization layer disposed between the transparent conductive layer and the third insulating layer or between the conductive layer and the second insulating layer.

7. The display panel as recited in claim 1, wherein the overlap of the first metal layer and the second metal layer forms a first capacitor, the overlap of the conductive layer and the transparent conductive layer forms a second capacitor, and the ratio of the capacitance of the second capacitor to the capacitance of the first capacitor is greater than 1 and less than 5.

8. The display panel as recited in claim 7, wherein the overlap of the second metal layer and the conductive layer forms a third capacitor, and the sum of the capacitances of the first capacitor, the second capacitor and the third capacitor is regarded as the capacitance of the capacitor structure.

9. The display panel as recited in claim 8, further comprising:
a color filter substrate disposed opposite the active-matrix substrate, wherein a liquid crystal layer is disposed between the color filter substrate and the active-matrix substrate;
wherein the active-matrix substrate comprises a plurality of pixel units, at least one of the pixel units corresponds to the capacitor structure and an LC capacitance of the liquid crystal layer, and the ratio of the capacitance of the capacitor structure to the LC capacitance is greater than 1.5 in each of the pixel units.

10. The display panel as recited in claim 1, wherein the active-matrix substrate comprises a plurality of pixel units, each of the pixel units has an aperture area, and the ratio of the area of the conductive layer to the area of the aperture area is less than 0.8.

11. The display panel as recited in claim 1, wherein the transparent conductive layer at least partially overlaps the second metal layer.

12. The display panel as recited in claim 6, wherein the thickness of the planarization layer is greater than the triple of the thickness of the first insulating layer.

13. The display panel as recited in claim 1, further comprising:
a color filter substrate disposed opposite the active-matrix substrate, wherein a liquid crystal layer is disposed between the color filter substrate and the active-matrix substrate;
wherein a capacitive touch structure is disposed on at least one side of the color filter substrate.

14. The display panel as recited in claim 13, wherein the capacitive touch structure is disposed between a filter layer and the color filter substrate.

15. The display panel as recited in claim 1, wherein the active-matrix substrate further comprises a plurality of pixel units disposed on the transparent substrate to form an array, each of the pixel units includes a first area and a second area, the first area and the second area comprise the corresponding capacitor structures and individually correspond to a first transparent conductive layer and a second transparent conductive layer, the first transparent conductive layer and the second transparent conductive layer are provided with different voltages.
